(19) United States
(12) Patent Application Publication
(10) Pub. No.: US 2026/0188623 A1
(43) Pub. Date: Jul. 2, 2026

(54) PLASMA CHAMBER DOME ATTACHMENT AND DETACHMENT JIG

(71) Applicant: SEMES CO., LTD., Cheonan-si (KR)

(72) Inventors: Nam Hun KIM, Cheonan-si (KR); Mun Hyeok HWANG, Cheonan-si (KR); Seung Hoon JEON, Cheonan-si (KR); Min Goo KANG, Cheonan-si (KR); Jung Ho SEO, Cheonan-si (KR); Young Hwan KIM, Cheonan-si (KR)

(73) Assignee: SEMES CO., LTD., Cheonan-si (KR)

(21) Appl. No.: 19/429,898

(22) Filed: Dec. 22, 2025

(30) Foreign Application Priority Data
Dec. 26, 2024 (KR) 10-2024-0197235

(51) Int. Cl. H01J 37/32

(52) U.S. Cl. CPC H01J 37/32458

(57) ABSTRACT

Disclosed relates to a jig for attaching and detaching an inner dome of a plasma chamber, particularly, to a plasma chamber dome attachment and detachment jig configured to easily attach and detach a dome to and from a central portion of a chamber frame without the use of a separate gauge, and the dome jig attaching and detaching the dome of the plasma chamber includes a base plate, and a plurality of raising and lowering units that are installed along an edge of the base plate and configured to move the base plate upward and downward.

### CROSS REFERENCE TO RELATED APPLICATION

The present application claims priority to Korean Patent Application No. 10-2024-0200786, filed Dec. 30, 2024, the entire contents of which are incorporated herein for all purposes by this reference.

### BACKGROUND OF THE INVENTION

### Field of the Invention

The present disclosure relates to a jig for attaching and detaching an inner dome of a plasma chamber. More particularly, the present disclosure relates to a plasma chamber dome attachment and detachment jig, which is configured to easily attach and detach a dome to and from a central portion of a chamber frame without the use of a separate gauge.

### Description of the Related Art

A substrate processing apparatus is commonly used in semiconductor device manufacturing to perform predetermined processes on substrates such as semiconductor wafers. The predetermined processes include a deposition process for forming a predetermined film on a substrate surface, an etching process for forming a predetermined pattern on the film formed on the substrate, and a cleaning process for physically or chemically cleaning the substrate surface.

A plasma process for a substrate processing apparatus is performed by supplying process gas into a plasma chamber and applying high-frequency voltage to either the upper or lower electrode, thereby exciting the gas beyond its reference energy state. Plasma is generated in a lifted state, and the substrate adsorbed onto a substrate support unit is plasma-treated.

Meanwhile, during the plasma processing, byproducts of plasma chemical reactions, such as deposited materials or residual compounds, accumulate in the chamber. This can degrade process consistency and cause defects in subsequent substrate processing, so periodic cleaning of the chamber and maintenance are required for the subsequent substrate processing. Furthermore, damaged or worn components in the chamber during the plasma process should be replaced, and process changes may require modifications to the chamber's design. Consequently, the operation of attaching and detaching a dome covering the chamber occurs frequently.

FIG. 5 is a view showing a method for attaching and detaching a dome of an existing plasma chamber. Conventionally, when the dome is attached to a chamber frame, a fabricator firmly attaches the dome to a surface using a separate vacuum absorbing device, and then manually locates the dome on a gasket. The fabricator aligns the dome concentrically with the chamber frame with a gauge (not shown) and then removes the gauge. However, when the dome weighs over 15 kg, it is difficult to easily align the dome and the chamber frame concentrically. During gauge removal, concentricity of the dome and the chamber may be misaligned, so that performance in subsequent processes may be degraded, and internal arcing may occur.

Furthermore, to remove the dome from the chamber for replacement or cleaning of components, a vacuum absorbing device is used to attach the surface of the dome. Afterward, the fabricator manually pulls them apart. At this time, a lower portion of the dome may be irregularly detached from the seating surface because the dome is fused to the gasket due to heat and pressure inside the chamber during the plasma process. During the detachment process, the direction of the fabricator's force may be changed unpredictably, and when the dome collides unintentionally with components installed around the chamber, high-value precision components can be easily damaged.

To remove this problem, the related art document KR 10-2008-0005662, which relates to a cover attachment and detachment apparatus equipped with a drive unit to detach a cover from a container body forming the chamber has been proposed. However, no device has been provided that can accurately align the dome's concentricity during installation, prevent collisions with surrounding components, and safely detach the dome.

### Documents of Related Art

(Patent Document 1) KR 10-2008-0005662 A (January 15, 2008)

### SUMMARY OF THE INVENTION

According to the present disclosure, there is provided a jig for attaching and detaching an inner dome of a plasma chamber, and an objective of the present disclosure is to provide a plasma chamber dome attachment and detachment jig, which is capable of precisely attaching a dome concentrically to a central portion of a plasma chamber frame and detaching the dome while maintaining a perpendicular detachment direction, without damage.

According to the embodiment of the present disclosure, there is provided a plasma chamber dome jig, the dome jig being configured to attach and detach a dome of a plasma chamber, and the dome jig includes: a base plate; and a plurality of raising and lowering units that are installed along an edge of the base plate and configured to move the base plate upward and downward.

According to the embodiment of the present disclosure, the base plate may have a form of a triangular flat plate, and the plurality of raising and lowering units may be provided on each vertex of the base plate.

According to the embodiment of the present disclosure, ach of the raising and lowering units may include: a guide frame as a support structure; a guide block located at a corresponding position relative to the guide frame, with the base plate located between the guide block and the guide frame; a screw rotatably coupled to both the guide frame and the guide block; and a nut coupled to the base plate and fitted over the screw, wherein, when the screw is rotated, the base plate is relatively moved with respect to the guide frame and the guide block.

According to the embodiment of the present disclosure, an end of the screw may further include a handle enabling the screw to be rotated.

According to the embodiment of the present disclosure, the guide frame may further include an indicator enabled to indicate information about the amount of rotation of the screw or the amount of relative rotation of the base plate with respect to the guide frame.

According to the embodiment of the present disclosure, the dome jig may further include: a plurality of guide shafts installed through the base plate and securely connecting the guide frame and the guide block to each other, and configured to guide the base plate when the base plate is relatively moved with respect to the guide frame and the guide block.

According to the embodiment of the present disclosure, the base plate through which each guide shaft penetrates may include a bush to be lubricated.

According to the embodiment of the present disclosure, the base plate may further include a vacuum absorbing device to adsorb the dome.

According to the embodiment of the present disclosure, a central portion of the base plate may have an attachment hole for the vacuum absorbing device to be attached, and the vacuum absorbing device may be secured in place through the attachment hole using a fixing member.

According to the embodiment of the present disclosure, the base plate may further include a towing hook for towing the base plate.

According to the embodiment of the present disclosure, the guide block may include a guide protrusion extending downward and forming a catching step enabled to perch on an edge of a chamber frame of the plasma chamber.

According to the embodiment of the present disclosure, an end of the guide block may provide a guide surface, and the guide surface may support an edge of the dome which remains adsorbed to the base plate.

According to the embodiment of the present disclosure, the base plate may further include a support member enabled to prevent a collision between the base plate and the dome adsorbed thereto.

As another aspect of the present disclosure, there is provided a plasma chamber dome jig according to the embodiment of the present disclosure, and dome jig may include: a base plate; and a plurality of raising and lowering units installed along an edge of the base plate and configured to move the base plate upward and downward, wherein each of the raising and lowering units may include: a guide frame as a support structure; a guide block located at a corresponding position relative to the guide frame, with the base plate located between the guide block and the guide frame; a screw rotatably coupled to both the guide frame and the guide block; a nut coupled to the base plate and fitted over the screw; and a motor provided at an end of the screw and enabled to rotate the screw, wherein when the screw is rotated by the motor, the base plate is relatively moved with respect to the guide frame and the guide block.

According to the embodiment of the present disclosure, the guide frame may further include an indicator from which information about the amount of rotation of the screw or the amount of relative rotation of the base plate with respect to the guide frame.

According to the embodiment of the present disclosure, the dome jig may further include: a plurality of guide shafts installed through the base plate and securely connecting the guide frame and the guide block to each other, and configured to guide the base plate when the base plate is relatively moved with respect to the guide frame and the guide block.

According to the embodiment of the present disclosure, the base plate may further include a vacuum absorbing device to adsorb the dome.

According to the embodiment of the present disclosure, the guide block may include a guide protrusion extending downward and forming a catching step enabled to perch on an edge of a chamber frame of the plasma chamber.

According to the embodiment of the present disclosure, the motor may be controllable by a remote controller.

As another aspect of the present disclosure, there is provided a plasma chamber dome jig according to the embodiment of the present disclosure, and the dome jig may include: a base plate having the form of a triangular flat plate; a plurality of raising and lowering units installed on each vertex of the base plate along an edge of the base plate and configured to move the base plate upward and downward; a vacuum absorbing device configured to adsorb the dome onto a lower portion of the base plate; and a towing hook for towing the base plate, wherein each of the raising and lowering units may include: a guide frame as a support structure; a guide block located at a corresponding position relative to the guide frame with the base plate located between the guide block and the guide frame; a screw rotatably coupled to both the guide frame and the guide block; a nut coupled to the base plate and fitted over the screw; a guide shaft configured to guide the base plate through the bush when the base plate is relatively moved with respect to the guide frame and the guide block; a handle enabled to rotate the screw; and an indicator enabled to indicate information about the amount of rotation of the screw or the amount of relative rotation of the base plate with respect to the guide frame, wherein when the screw is rotated by the handle, the base plate is relatively moved with respect to both the guide frame and the guide block.

According to the embodiment of the present disclosure, the dome jig can precisely attach the dome concentrically to the central portion of the plasma chamber frame, so that no loss of efficiency occurs in subsequent processes, and no arcing occurs internally.

According to the embodiment of the present disclosure, the dome can be detached from the frame while maintaining the perpendicular dome detachment direction, thus preventing the dome from colliding with the components, allowing the dome to be detached without damage to the components.

According to the embodiment of the present disclosure, the dome fused to the gasket can be precisely detached using the shaft force of the screws with the plurality of raising and lowering units provided at the base plate and the indicator.

### BRIEF DESCRIPTION OF THE DRAWINGS

FIG. 1 is a view showing schematic configuration of a dome

attachment and detachment jig of a plasma chamber according to an embodiment of the present disclosure.

FIG. 2 is a side sectional view showing the dome attachment and detachment jig of the plasma chamber according to the embodiment of the present disclosure.

FIG. 3 is a view showing a method of use of the dome attachment and detachment jig of the plasma chamber according to the embodiment of the present disclosure.

FIG. 4 is a view showing a precise dome attachment method using a raising and lowering unit of the dome attachment and detachment jig of the plasma chamber according to the embodiment of the present disclosure.

FIG. 5 is a view showing a problem according to a dome attachment and detachment method of a conventional plasma chamber.

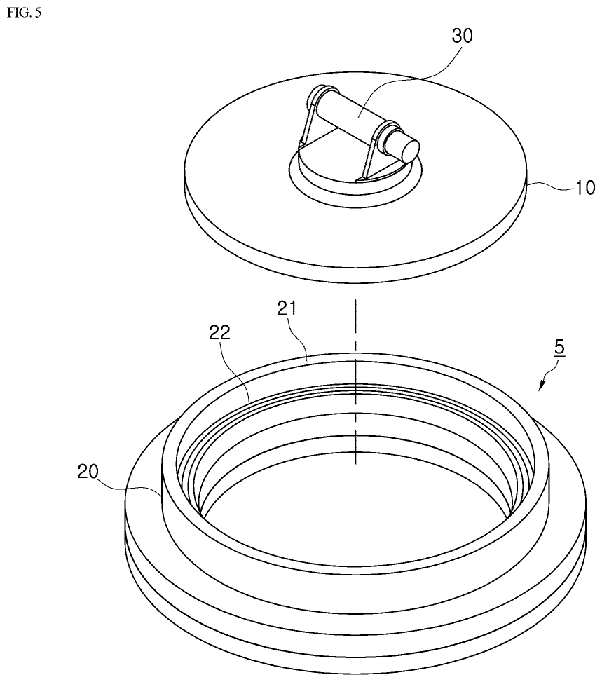

### DETAILED DESCRIPTION OF THE DISCLOSURE

Hereinbelow, embodiments of the present disclosure will be described in detail with reference to the accompanying drawings such that the present disclosure can be easily embodied by one of ordinary skill in the art to which the present disclosure belongs. However, the present disclosure may be implemented in several different forms and is not limited to the embodiments described hereinbelow.

In describing the embodiments of the present disclosure, if it is determined that a specific description of a related known function of configuration may unnecessarily obscure the gist of the present disclosure, specific description is omitted, and parts in which similar functions or operations are performed will use the same reference numerals throughout the drawings.

Furthermore, in various embodiments, elements with the same configuration will be described in a representative embodiment by using the same reference numeral, and different configurations from the representative embodiment will be described in other embodiments.

In the specification, it will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

### First Embodiment

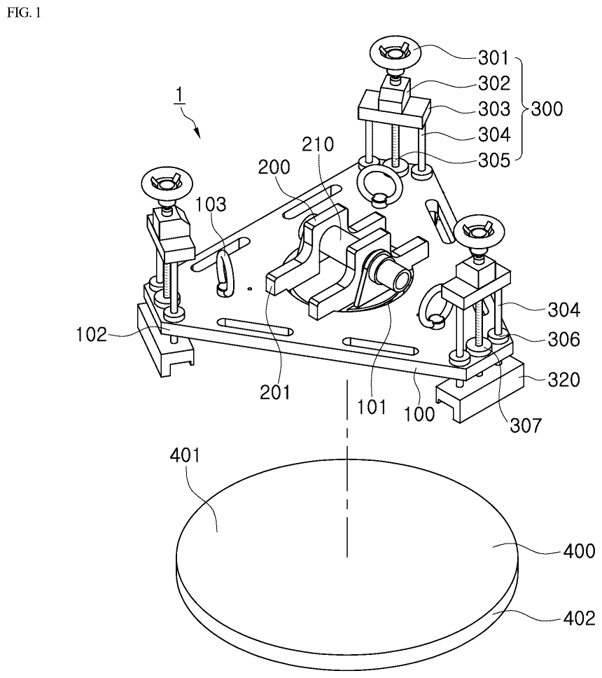

FIG. 1 is a view showing a schematic configuration of a dome attachment and detachment jig of a plasma chamber according to an embodiment of the present disclosure. Referring to FIG. 1, according to the embodiment of the present disclosure, a dome attachment and detachment jig 1 includes a plurality of raising and lowering units 300 arranged along the edge of a base plate 100, and the plurality of raising and lowering units 300 adsorbs a dome 400 and raises and lowers the dome 400. The base plate 100 may generally have the form of a triangular flat plate, but is not limited thereto, and may have various forms such as a circle or a quadrilateral. When the base plate 100 is a triangular flat plate, each raising and lowering unit 300 may be installed at a portion adjacent to each vertex of a triangle.

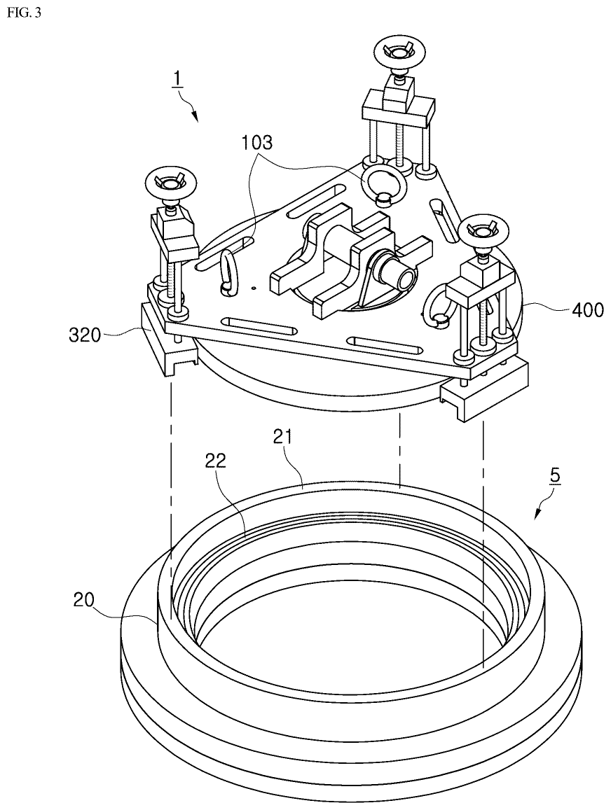

Each of the raising and lowering units 300 includes a guide frame 303 as a support structure, and a guide block 320 at a corresponding position relative to the guide frame 303 with the base plate 100 located between the guide frame and the guide block. The guide block 320 comes into close contact with a dome edge 402 of the dome 400, so that the dome 400 may be located concentrically with a chamber frame 20 (referring to FIG. 3). The mechanism of the guide block 320 will be described in detail later.

The guide frame 303 and the guide block 320 are connected to each other to be rotatable with a thread screw 305, and the screw 305 is coupled to the guide frame 303 and the guide block 320 through a nut 307 attached to the base plate 100. More specifically, the screw 305 is rotated with respect to the guide frame 303 and the guide block 320, and is moved upward and downward by the nut 307. On the other hand, when the screw 305 is rotated, the base plate 100 with the nut 307 coupled thereto may be moved upward and downward relatively to the guide frame 303 or the guide block 320.

Meanwhile, each raising and lowering unit may include guide shafts 304 at left and right spaces of the screw 305 to securely connect the guide frame 303 and the guide block 320 to each other. The guide shafts 304 may be moved freely upward and downward through guide bushes 306 provided on the base plate 100. When the base plate 100 is moved upward and downward as the screw 305 is rotated, the guide shafts 304 guide the base plate 100 to allow the base plate 100 to be moved precisely upward and downward without horizontal gaps.

According to the embodiment of the present disclosure, the dome attachment and detachment jig 1 of the plasma chamber may include a handle 301 on an upper portion of the guide frame 303 to rotate the screw 305. Furthermore, the dome attachment and detachment jig 1 of the plasma chamber may include an indicator 302 from which the amount of rotation of the handle 301 or the vertical displacement of the base plate 100 with respect to the screw 305 can be checked. When a fabricator checks the information displayed on the indicator 302 and rotates the handle 301 to rotate the screw 305, the base plate 100 is moved upward and downward relative to the guide frame 303 or the guide block 320 by the nut 307. In other words, while the handle 301 of the plurality of raising and lowering units 300 is finely adjusted, the base plate 100 and the dome 400, which is adsorbed onto the base plate, can be precisely moved upward and downward.

Meanwhile, according to the embodiment of the present disclosure, the base plate 100 of the dome attachment and detachment jig 1 of the plasma chamber may include an attachment hole 101 at a central portion to attach the vacuum absorbing device 210. In the attachment hole 101, the vacuum absorbing device 210 or a self-designed separate absorbing device 210 by vacuum suction may be fixed by an absorbing device fixing member 200. In FIG. 1, the view shows a structure of the absorbing device fixing member 200 having two frames, and fixation protrusions 201 are provided on opposite ends thereof and extend outward from the attachment hole 101 to fix the vacuum absorbing device 210 to the base plate 100, but the structure is not limited thereto.

According to the embodiment of the present disclosure, the vacuum absorbing device 210 attached to the base plate 100 adsorbs a dome upper surface 401 of a dome 400, and the plurality of guide blocks 320 of the raising and lowering units 300 come into close contact with the dome edge 402 of the dome 400. Accordingly, the base plate 100 and the dome 400 may be moved upward, downward, leftward, and rightward as an integrated body by a separate crane (not shown).

According to the embodiment of the present disclosure, the dome attachment and detachment jig 1 of the plasma chamber may include a towing hook 103 to locate the jig 1 adsorbing the dome 400 on an upper portion of the chamber frame 20 of the plasma chamber 5. The towing hook 103 may be provided at a portion adjacent to each vertex of the triangular base plate 100 to allow the dome jig 1 to be easily balanced, as shown in FIG. 1. Generally, the weight and size of the dome 400 of the plasma chamber 5 are approximately 15 kg and 0.6 m, making it quite heavy. The weight of the jig 1 may be approximately 10 kg, and it is preferable to include the towing hook 103 for lifting the dome.

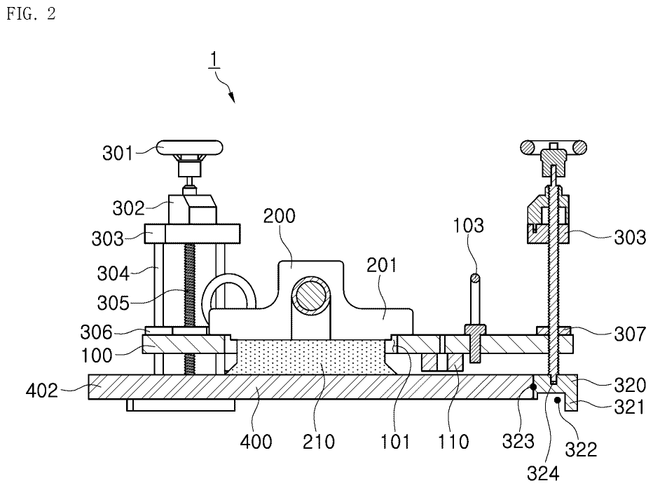

Next, referring to FIG. 2, the dome attachment and detachment jig 1 of the plasma chamber according to the embodiment of the present disclosure will be described in detail. As shown in FIG. 2, the guide block 320 of the present disclosure has a section approximately shaped in a “┐” form. The guide block 320 includes a guide protrusion 321 downward in a direction of attaching the dome 400, and includes a catching step 322 that may perch on a frame edge 21 (referring to FIG. 3) of the chamber frame 20 of the plasma chamber 5. Furthermore, an end of the guide block 320 toward the base plate 100 includes a guide surface 323, and the guide surface 323 may closely support a dome edge 402 (referring to FIG. 1) of the dome 400. A plurality of guide surfaces 323 secures the dome edge 402 toward the center of the base plate 100, so that the center portion of the dome 400 and the center portion of the base plate 100 may be aligned concentrically. As shown in FIG. 2, an end of the screw 305 includes a rotatable coupling part 324 that is rotatable with the guide block 320 but remains coupled to the guide block 320.

Meanwhile, according to the embodiment of the present disclosure, the dome attachment and detachment jig 1 of the plasma chamber may include a plurality of support members 110 that are provided at a lower portion of the base plate 100 in a direction of adsorbing the dome 400. The plurality of support members 110 is a type of shock absorber made from a material that can absorb shocks, such as urethane foam, etc. As shown in FIG. 1, when the base plate 100 is triangular, three support members 110 may be attached to the base plate at an interval of 120 degrees. The support members 110 prevent the dome 400 from colliding or being damaged by the base plate 100 due to gaps between the vacuum absorbing device 210 and the dome 400.

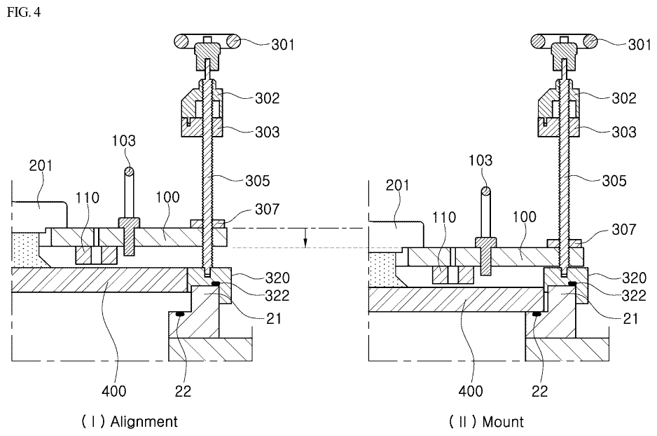

Next, referring to FIGS. 3 and 4, according to the embodiment of the present disclosure, a method of attaching and detaching the dome 400 using the dome attachment and detachment jig 1 of the plasma chamber will be described in detail.

When attaching the dome 400, first, a hook of the crane (not shown) is attached to the towing hook 103 so that the jig 1 of the present disclosure is positioned above the dome 400. Next, the crane is activated to lower the jig 1 so that the guide surface 323 of the guide block 320 comes into contact with the dome edge 402 of the dome 400. When the guide surface 323 comes into contact with the dome edge 402 and the centers of the base plate 100 and the dome 400 coincide concentrically, each handle 301 is rotated to rotate each screw 305, adjusting the base plate 100 so that the base plate 100 is close to the dome 400. Since the jig 1 of the present disclosure includes a plurality of raising and lowering units 300, the base plate 100 may be adjusted to be lowered concentrically with the dome 400 by rotating the plurality of handles 301. At this point, the raising and lowering heights of the base plate 100 may be finely adjusted in reference to the information provided from the indicator 302 installed at the guide frame 303.

Next, when the base plate 100 is moved close enough to the dome 400 to allow the vacuum absorbing device 210 to adsorb the dome upper surface 401 of the dome 400, vacuum is applied to the vacuum absorbing device 210 to adsorb and support the dome 400. In this state, the vacuum absorbing device 210 securely supported by the base plate 100 adsorbs and supports the dome upper surface 401 of the dome 400, and simultaneously a plurality of guide surfaces 323 of a plurality of guide blocks 320 of a plurality of raising and lowering units 300 supports the dome edge 402 of the dome 400 at a plurality of positions, thus closely supporting the dome 400 by the base plate 100.

Next, as shown in FIG. 3, the assembly of the jig 1 and the dome 400 is raised to the upper portion of the chamber frame 20 of the plasma chamber 5 by using the crane (not shown). When the assembly is carefully lowered, the plurality of guide blocks 320 eventually perches on the frame edge 21 of the plasma chamber 5. In more detail, as shown in FIG. 4, the catching step 322 of the guide block 320 closely perches on the frame edge 21. The jig 1 of the present disclosure is configured such that the guide block 320 of the raising and lowering units 300 precisely perches on the frame edge 21 and the center of the dome 400 supported by the guide surface 323 is accurately aligned to the center portion of the frame edge 21, allowing the dome 400 to be seated.

When the crane (not shown) moves the assembly of the jig 1 and the dome 400, a collision may occur due to shaking caused by gaps between the dome 400 and the base plate 100. However, the jig 1 of the present disclosure includes a plurality of support members 110 under the base plate 100, thereby preventing a collision between the dome and the base plate.

Next, as shown in FIG. 4, the assembly structure of the base plate 100 and the dome 400 is lowered by rotating the handles 301 of the raising and lowering units 300 of the jig 1 of the present disclosure. The screws 305 are rotated according to the rotation of the handles 301, whereby lowering the base plate 100 and the dome 400, which is securely attached to the base plate, due to the nuts 307 coupled to the screws 305. The fabricator alternately rotates a plurality of handles 301 based on the information from the indicator 302 and carefully places the dome 400 to a gasket 22 of the chamber frame 20.

Finally, the vacuum applied to the vacuum absorbing device 210 is removed, and the jig 1 is removed, thereby completing the attachment of the dome 400. Simultaneously, the guide block 320 serving as an existing gauge is removed, thereby fundamentally preventing the center of the dome 400 from being deformed by external force.

Meanwhile, a method for removing the dome 400 to clean the plasma chamber 5 or replace components will be described in detail.

First, the jig 1 of the present disclosure is attached to the frame edge 21 of the chamber frame 20. The catching step 322 of each guide block 320 of the present disclosure is designed to precisely perch on the frame edge 21, so the base plate 100 is located precisely above the dome 400. Next, the handles 301 are rotated to lower the base plate 100 close to the dome 400, allowing the vacuum absorbing device 210 to adsorb the upper surface 401 of the dome 400. When the vacuum absorbing device 210 comes into close contact with the dome upper surface 401, a vacuum is applied to the vacuum absorbing device 210, so that the dome 400 is adsorbed and secured to the base plate 100.

Next, the base plate 100, which adsorbs and secures the dome 400, is raised by rotating a plurality of handles 301 in the reverse direction. Based on a value from the indicator 302 attached like the handle 301, a plurality of screws 305 is rotated in equal amounts, little by little, thereby detaching the dome 400 fused to the gasket 22 with shaft rotating forces of the screws 305. An even force is applied to a plurality of raising and lowering units 300, while the units 300 are finely adjusted using the handle 301 and the indicator 302, and this prevents the components attached to the plasma chamber 5 from being damaged due to momentary shaking of the dome 400 in the detachment process.

### Second Embodiment

Next, a second embodiment of the present disclosure will be described compared to the first embodiment. Parts differing from the first embodiment are described in detail, and the redundant parts are omitted in the following description. However, the second embodiment of the present disclosure is not limited thereto.

According to the second embodiment of the present disclosure, the dome attachment and detachment jig 1 includes a plurality of raising and lowering units 300 along the edge of the base plate 100 to adsorb the dome 400 and move it upward and downward. Each raising and lowering unit 300 includes a remote control member by which the fabricator can operate each raising and lowering unit 300 using a remote controller (not shown).

As an example of the present disclosure, instead of the handle 301 in FIG. 1, a plurality of raising and lowering units 300 includes a motor (not shown) of which revolution may be finely bi-directionally controlled, and the motor is connected to the screw 305 and rotates the screw 305. Furthermore, the indicator 302 of each of the raising and lowering units 300 may be electrically and electronically connected to the motor (not shown) so as to be controlled with feedback.

The fabricator can raise and lower the base plate 100 and the dome 400 adsorbed to the base plate 100 further precisely by using the dome attachment and detachment jig 1 according to the second embodiment of the present disclosure. For example, the fabricator can push a separate lowering button of the remote controller (not shown) to precisely lower the adsorbed assembly of the base plate 100 and the dome 400. Furthermore, the fabricator can push a separate raising button of the remote controller (not shown) to precisely raise the adsorbed assembly of the base plate 100 and the dome 400.

The jig of the present disclosure is not limited to the above-described attachment and/or detachment of the dome 400, and may be used to attach and/or detach an upper structure facing a substrate support part in the plasma chamber 5, for example, an upper electrode, a shower head, a window, and the like.

Although the embodiments of the present disclosure have been disclosed for illustrative purposes, those skilled in the art will appreciate that various modifications, additions and substitutions are possible, without departing from the scope and spirit of the present disclosure as disclosed in the accompanying claims. Since the present disclosure may be embodied in other specific forms without changing the technical sprit or essential features, those skilled in the art to which the present disclosure belongs should understand that the embodiments described above are exemplary and not intended to limit the present disclosure.

Therefore, the spirit of the present disclosure will not be defined by the accompanying claims rather than by the detailed description, and those skilled in the art should understand that various modifications, additions and substitutions derived from the meaning and scope of the present disclosure and the equivalent concept thereof are included in the scope of the present disclosure.

What is claimed is:

1. A dome jig of a plasma chamber to attach or detach a dome of the plasma chamber, the dome jig comprising:
a base plate; and
a plurality of raising and lowering units installed along an edge of the base plate and configured to move the base plate upward and downward.

2. The dome jig of claim 1,
wherein the base plate has a form of a triangular flat plate, and
the plurality of raising and lowering units is provided on each vertex of the base plate.

3. The dome jig of claim 1,
wherein each of the plurality of raising and lowering units comprises:
a guide frame as a support structure;
a guide block located at a corresponding position relative to the guide frame, with the base plate located between the guide block and the guide frame;
a screw rotatably coupled to both the guide frame and the guide block; and
a nut coupled to the base plate and fitted over the screw, wherein, when the screw is rotated, the base plate is relatively moved with respect to the guide frame and the guide block.

4. The dome jig of claim 3,
wherein an end of the screw further comprises a handle enabling the screw to be rotated.

5. The dome jig of claim 3,
wherein the guide frame further comprises an indicator enabled to indicate information about the amount of rotation of the screw or the amount of relative rotation of the base plate with respect to the guide frame.

6. The dome jig of claim 3, further comprising:
a plurality of guide shafts installed through the base plate and securely connecting the guide frame and the guide block to each other, and configured to guide the base plate when the base plate is relatively moved with respect to the guide frame and the guide block.

7. The dome jig of claim 6, further comprising:
a guide bush provided on the base plate,
wherein each guide shaft penetrates the base plate via the guide bush.

8. The dome jig of claim 1,
wherein the base plate further comprises a vacuum absorbing device to adsorb the dome.

9. The dome jig of claim 8,
wherein a central portion of the base plate has an attachment hole for the vacuum absorbing device to be attached, and the vacuum absorbing device is secured in place through the attachment hole using a fixing member.

10. The dome jig of claim 1,
wherein the base plate further comprises a towing hook for towing the base plate.

11. The dome jig of claim 3,
wherein the guide block includes a guide protrusion extending downward and forming a catching step enabled to perch on an edge of a chamber frame of the plasma chamber.

12. The dome jig of claim 11,
wherein an end of the guide block provides a guide surface, and
the guide surface supports an edge of the dome which remains adsorbed to the base plate.

13. The dome jig of claim 8,
wherein the base plate further comprises a support member enabled to prevent a collision between the base plate and the dome adsorbed thereto.

14. A dome jig of a plasma chamber to attach or detach a dome of the plasma chamber, the dome jig comprising:
a base plate; and
a plurality of raising and lowering units installed along an edge of the base plate and configured to move the base plate upward and downward,
wherein each of the plurality of raising and lowering units comprises:
a guide frame as a support structure;
a guide block located at a corresponding position relative to the guide frame, with the base plate located between the guide block and the guide frame;
a screw rotatably coupled to both the guide frame and the guide block;
a nut coupled to the base plate and fitted over the screw; and
a motor provided at an end of the screw and enabled to rotate the screw, wherein when the screw is rotated by the motor, the base plate is relatively moved with respect to the guide frame and the guide block.

15. The dome jig of claim 14,
wherein the guide frame further comprises an indicator from which information about the amount of rotation of the screw or the amount of relative rotation of the base plate with respect to the guide frame.

16. The dome jig of claim 14, further comprising:
a plurality of guide shafts installed through the base plate and securely connecting the guide frame and the guide block to each other, and configured to guide the base plate when the base plate is relatively moved with respect to the guide frame and the guide block.

17. The dome jig of claim 14,
wherein the base plate further comprises a vacuum absorbing device to adsorb the dome.

18. The dome jig of claim 14,
wherein the guide block includes a guide protrusion extending downward and forming a catching step enabled to perch on an edge of a chamber frame of the plasma chamber.

19. The dome jig of claim 14,
wherein the motor is controllable by a remote controller.

20. A dome jig of a plasma chamber to attach or detach a dome of the plasma chamber, the dome jig comprising:
a base plate having the form of a triangular flat plate and provided with a guide bush;
a plurality of raising and lowering units installed on each vertex of the base plate along an edge of the base plate and configured to move the base plate upward and downward;
a vacuum absorbing device configured to adsorb the dome onto a lower portion of the base plate; and
a towing hook for towing the base plate,
wherein each of the plurality of raising and lowering units comprises:
a guide frame as a support structure;
a guide block located at a corresponding position relative to the guide frame with the base plate located between the guide block and the guide frame;
a screw rotatably coupled to both the guide frame and the guide block;
a nut coupled to the base plate and fitted over the screw;
a guide shaft configured to guide the base plate through the bush during relative movement of the guide base plate with respect to the guide frame and the guide block;
a handle enabled to rotate the screw; and
an indicator enabled to indicate information about the amount of rotation of the screw or the amount of relative rotation of the base plate with respect to the guide frame, and
wherein when the screw is rotated by the handle, the base plate is relatively moved with respect to both the guide frame and the guide block.
